(19) United States
(12) Patent Application Publication
(10) Pub. No.: US 2017/0103899 A1
(43) Pub. Date: Apr. 13, 2017

(54) SEMICONDUCTOR STRUCTURE AND METHOD FOR FORMING THE SAME

(71) Applicant: ZING SEMICONDUCTOR CORPORATION, Shanghai (CN)

(72) Inventor: DEYUAN XIAO, Shanghai (CN)

(21) Appl. No.: 15/166,032

(22) Filed: May 26, 2016

(30) Foreign Application Priority Data
Oct. 13, 2015 (CN) 201510659197.4

(51) Int. Cl. H01L 21/30; H01L 29/66

(52) U.S. Cl. CPC H01L 21/3003; H01L 29/66545

(57) ABSTRACT

The present invention relates to a semiconductor structure and a method for forming the same. The method comprises steps of providing a substrate having a dummy gate, forming a source/drain epitaxy layer doped with deuterium at two sides of the dummy gate on the substrate through a process of chemical vapor deposition for epitaxy; removing the dummy gate and forming a gate structure having a gate oxide layer introducing the deuterium. Because the deuterium is introduced into the gate oxide layer, stable covalent bonds are formed at interface of the gate oxide layer to decrease the number of the dangling bonds. Also, recovery ability of devices when facing hot carrier effect may be improved, and influence of the hot carrier effect on the performance of the devices may be lowered.

### FIELD OF THE INVENTION

The present invention generally relates to semiconductor fabrication, and more particularly, certain embodiments of the invention relate to a semiconductor structure and method for forming a semiconductor structure.

### BACKGROUND OF THE INVENTION

Recently, development of semiconductor fabrication technology flourishes in many categories. Please refer to FIGS. 1-6, fabrication of a common metal oxide semiconductor (MOS) device is shown. At first, a gate structure is formed on a substrate, as shown in FIG. 1. Then, a passivation layer is deposited on the substrate covering the gate structure, reactive ion etching (ME) is carried out to remove a part of the passivation layer and tilt the both sides of the gate structure, and the part of the passivation layer above the substrate is further removed to form side walls of a gate, as shown in FIGS. 2-4. Then, source and drain gates are formed by epitaxial growth at two sides of the gate, and in situ doping is carried out, as shown in FIG. 5. At last, annealing is carried out to allow the doping ions entering the substrate to form a diffusion layer, as shown in FIG. 6.

However, dangling bonds, which mainly occurs upon surfaces or interfaces between layers in the semiconductor structures, comprising but not limited to what is formed according to aforesaid example, will cause holes, dislocations, and impurities trapped, etc.

Further, another problem in the MOS fabrication process is hot carriers which affect the performance of the MOS devices. When the MOS devices operate at higher voltages, carriers in the channel with efficient energy may enter insulating layer to affect the performance of the MOS devices, especially for those with small size.

### SUMMARY OF THE INVENTION

An object of the present invention is to provide a semiconductor structure and method for forming a semiconductor structure to decrease the number of dangling bonds or solve the problem caused by hot carriers.

To solve one of the aforesaid problems or improve or keep performance of devices, according to an aspect of the present invention, it is provided with a method for forming a semiconductor structure, comprising steps of providing a semiconductor substrate formed with at least one dummy gate, forming a source/gate epitaxy layer doped with deuterium atoms at the two sides of the dummy gate through a vapor phase epitaxy process, removing the dummy gate, and forming a gate structure comprising a gate oxide layer at the position where the dummy gate was formed. The deuterium atoms enter the gate oxide layer.

The method may be implemented into variable modifications. For example, the semiconductor substrate may be implemented by an extremely-thin silicon-on-insulator substrate, the vapor phase epitaxy process may comprise a step of forming the source/gate epitaxy layer doped with deuterium atoms with silicon-based gas and deuterium-based gas, the volume ratio of the deuterium-based gas may be within 50% to 90%, the deuterium-based gas may be deuterium gas or a mixture of deuterium gas and hydrogen gas, which volume ratio with respect to the total volume of the mixture may be within 2% to 98%, the silicon-based gas may comprise at least one compound or combination of compounds chosen from a group of SiH₄, Si₂H₆, SiH₂Cl₂, SiHCl₃, SiCl₄, Si(CH₃)₄, a temperature to perform the vapor phase epitaxy process may be within 800° C. to 1100° C., the duration of the vapor phase epitaxy process may be within 10 mins to 2000 mins, and/or a thickness of the source/gate epitaxy layer is within 10 nm to 5000 nm.

According to another aspect of the present invention, a semiconductor structure, which is manufactured by aforesaid method, is provided. The semiconductor structure comprises a semiconductor substrate, formed with a source/gate epitaxy layer doped with deuterium atoms, and a gate structure, formed between the source/gate epitaxy layer doped with deuterium atoms above the semiconductor substrate, comprising a gate oxide layer doped with deuterium atoms.

Compared with current technology, the method disclosed in the present invention comprises steps of providing a semiconductor substrate formed with at least one dummy gate, forming a source/gate epitaxy layer doped with deuterium atoms at the two sides of the dummy gate through a vapor phase epitaxy process, removing the dummy gate, and forming a gate structure comprising a gate oxide layer which the deuterium atoms enter at the position where the dummy gate was formed. As such, the manufactured semiconductor structure is formed with stable covalent bonds at the interface of the gate oxide layer to reduce the undesired effect of the dangling bonds because of the deuterium atoms entering the gate oxide layer. Further, because the covalent bonds are formed, the restortion of the devices is promoted when they face hot carrier effect, and thus the adverse effect of the hot carriers upon the performance of the device is reduced.

### BRIEF DESCRIPTION OF THE DRAWINGS

Various objects and advantages of the present invention will be more readily understood from the following detailed description when read in conjunction with the appended drawing, in which:

FIGS. 1-6 show a cross-section view of several statuses of a semiconductor structure during fabrication processes according to the current technology;

FIG. 7 shows a flow chart of the method for forming a semiconductor structure according to the present invention;

FIGS. 8-11 show a cross-section view of several statuses of a semiconductor structure during fabrication processes according to the present invention.

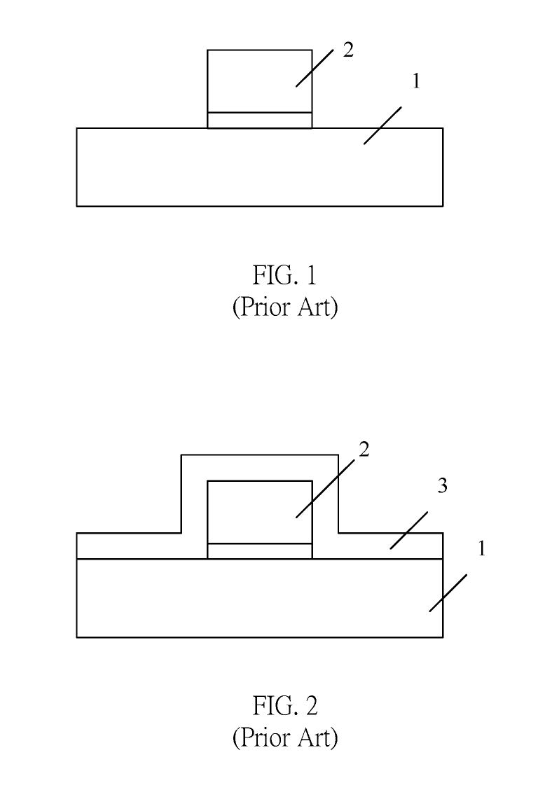

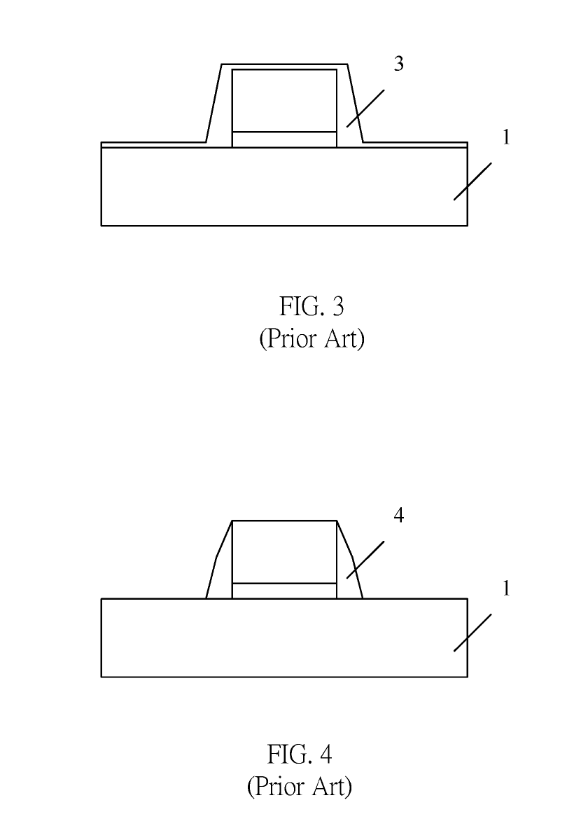

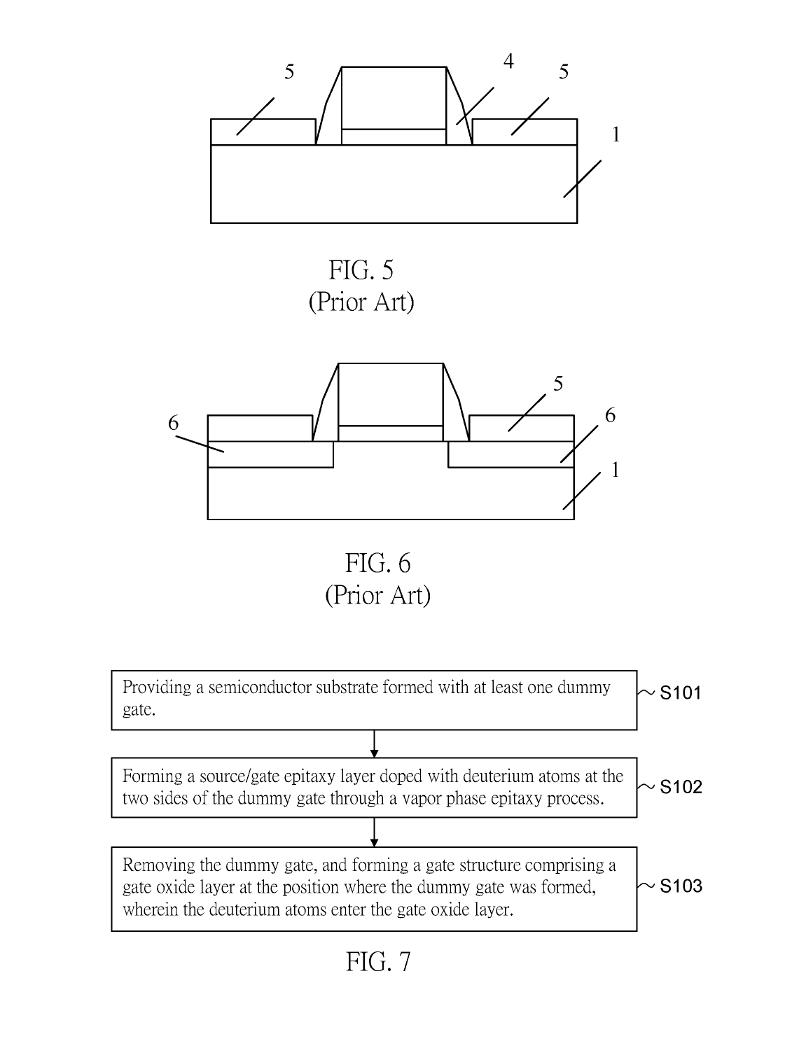

### DESCRIPTION OF EMBODIMENTS OF THE INVENTION

For a more complete understanding of the present disclosure and its advantages, reference is now made to the following description taken in conjunction with the accompanying drawings, in which like reference numbers indicate like features. Persons having ordinary skill in the art will understand other varieties for implementing example embodiments, including those described herein. The drawings are not limited to a specific scale and similar reference numbers are used for representing similar elements. As used in the disclosures and the appended claims, the terms “example embodiment,” “exemplary embodiment,” and “present embodiment” do not necessarily refer to a single embodiment, although it may, and various example embodiments may be readily combined and interchanged, without departing from the scope or spirit of the present disclosure. Furthermore, the terminology as used herein is for the purpose of describing example embodiments only and is not intended to be a limitation of the disclosure. In this respect, as used herein, the term “in” may include “in” and “on”, and the terms “a”, “an” and “the” may include singular and plural references.

The present invention provides a semiconductor structure and a method for forming the same. The method comprises steps of providing a semiconductor substrate formed with at least one dummy gate, forming a source/gate epitaxy layer doped with deuterium atoms at the two sides of the dummy gate through a vapor phase epitaxy process, removing the dummy gate, and forming a gate structure comprising a gate oxide layer at the position where the dummy gate was formed. The deuterium atoms enter the gate oxide layer. Though these steps, deuterium atoms are introduced into the gate oxide layer to promote the performance of the devices.

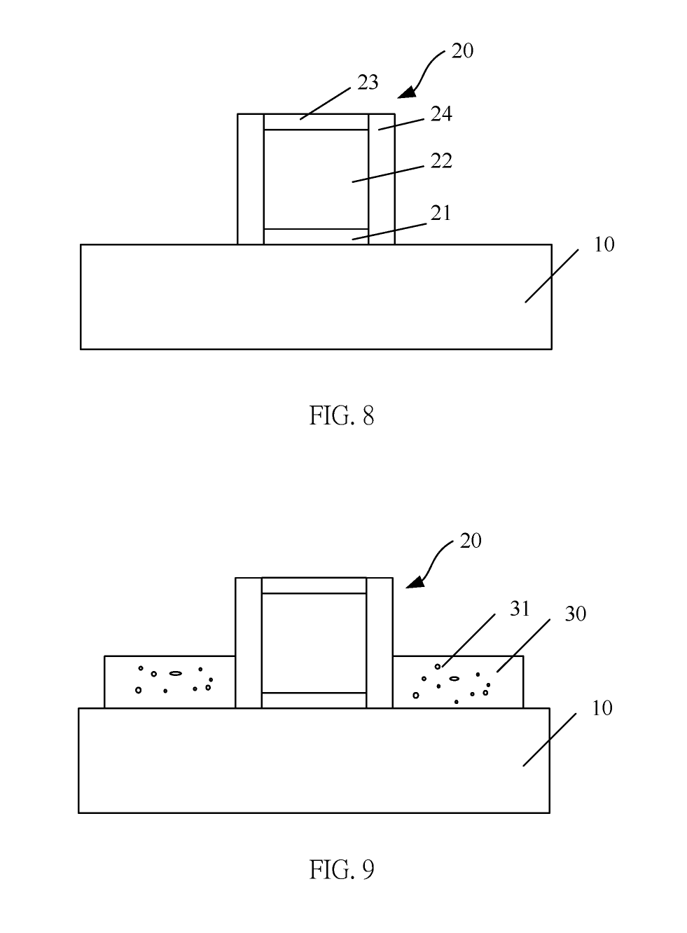

Here, please refer to FIGS. 7-11 for the details about the semiconductor structure and method for forming the same according to the present invention. FIG. 7 shows a flow chart of the method for forming a semiconductor structure according to the present invention, and FIGS. 8-11 show a cross-section view of several statuses of a semiconductor structure during fabrication processes according to the present invention.

According to the method for forming a semiconductor structure shown in FIG. 7 and the along with FIG. 8, firstly, step S101 is performed to provide a substrate 10 on which a dummy gate 20 is formed. Preferably, the substrate 10 is implemented by an extremely thin silicon-on-insulator substrate (ETSOI). The dummy gate 20 for instance may comprise a dummy-gate oxide layer 21, a polysilicon chunk 22, a photomask layer 23 and sidewalls 24. The dummy gate 24 may be implemented as a gate last, which is common in the current technology.

Cleaning or some other routine step(s) are optional afterwards, and details for this are omitted here.

Then, as shown in FIG. 7, step S102 is performed. A source/drain epitaxy layer 30 doped with deuterium atoms 31 is formed at the two sides of the dummy gate 20 through a vapor phase epitaxy process. Specifically, during the vapor phase epitaxy process, silicon-based gas and deuterium-based gas are utilized for forming the source/drain epitaxy layer 30 doped with deuterium atoms 31. Here, for instance, the volume ratio of the deuterium-based gas may be within 50% to 90%, the deuterium-based gas may be deuterium gas or a mixture of deuterium gas and hydrogen gas, which volume ratio with respect to the total volume of the mixture may be within 2% to 98%, the silicon-based gas may comprise at least one compound or combination of compounds chosen from a group of SiH₄, Si₂H₆, SiH₂Cl₂, SiHCl₃, SiCl₄, Si(CH₃)₄.

Preferably, a temperature to perform the vapor phase epitaxy process may be within 800° C. to 1100° C., and the duration of the vapor phase epitaxy process may be within 10 mins to 2000 mins, and then, a thickness of the source/gate epitaxy layer 30, which is within 10 nm to 5000 nm may be produced.

Gas content, temperature setting, and reactant duration may be variable to meet actual requirements to produce desirable source/gate epitaxy layer 30.

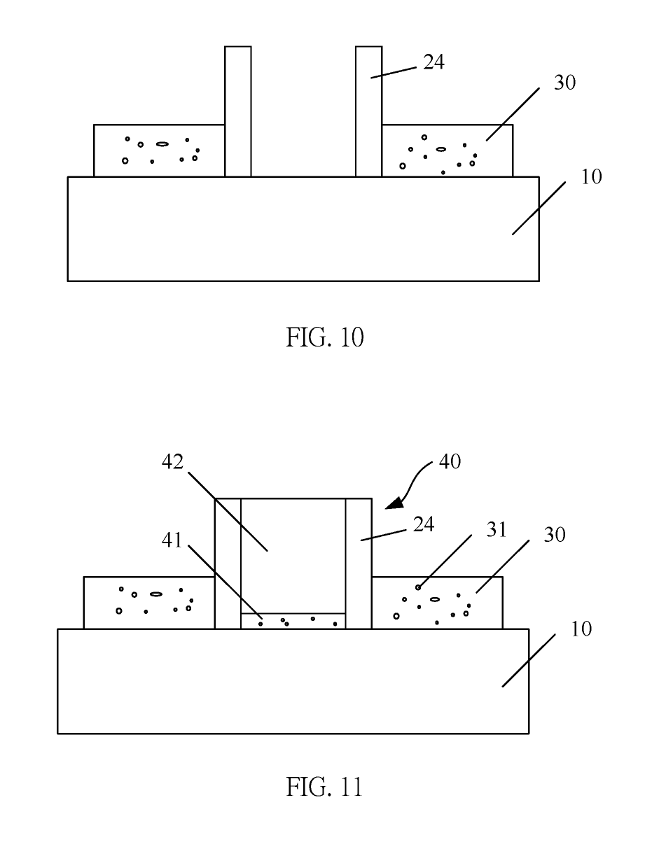

Then, as shown in FIGS. 10-11, step S103 is performed. The dummy gate 20 is removed and a gate structure 40 with a gate oxide layer 41 is formed at the place where the dummy gate 20 was formed. The deuterium atoms 31 enter the gate oxide layer 41. Specifically, the gate oxide layer 21, polysilicon chunk 22 and photomask layer 23 of the dummy gate 20 are all removed. Photoresist is utilized to cover the area other than the dummy gate 20 and then wet etching is performed until the gate oxide layer 21, polysilicon chunk 22 and photomask layer 23 of the dummy gate 20 are removed. Afterwards, at a temperature within 500° C. to 1150° C., another gate oxide layer 41 and gate chunk 42, such as high-k dielectric layer, metal gate, etc., above the gate oxide layer 41 are formed to build up the final gate structure 40. Because the temperature to form the gate oxide layer 41 is high enough to enable diffusion of the deuterium atoms 31 of the source/gate epitaxy layer 30. The deuterium atoms 31 may be introduced into the gate oxide layer 41 and gathered around the interfaces and therefore eventually the formation of stable Si-D covalent bonds may be benefited by the deuterium atoms 31 existing around the interfaces after the gate structure 40 is formed.

Please refer to FIG. 11, after the step S103, a semiconductor structure is provided. The semiconductor structure comprises a semiconductor substrate 10, formed with a source/gate epitaxy layer 30 doped with deuterium atoms 31, and a gate structure 40, formed between the source/gate epitaxy layer 30 doped with deuterium atoms 31 above the semiconductor substrate 10, comprising a gate oxide layer 41 doped with deuterium atoms 31.

The semiconductor structure obtained by performing aforesaid steps is formed with the covalent bonds at the interfaces of the gate oxide layer 41, and this may reduce adverse effect of the dangling bonds, and promote the restortion of the devices when they face hot carrier effect. Thus, the adverse effect of the hot carriers upon the performance of the device is reduced.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1. A method for forming a semiconductor structure, comprising steps of:
providing a semiconductor substrate formed with at least one dummy gate;
forming a source/drain epitaxy layer doped with deuterium atoms at the two sides of the dummy gate through a vapor phase epitaxy process;
removing the dummy gate; and
forming a gate structure comprising a gate oxide layer at the position where the dummy gate was formed,
wherein the deuterium atoms enter the gate oxide layer.

2. The method for forming a semiconductor structure according to claim 1, wherein the semiconductor substrate is an extremely thin silicon-on insulator substrate.

3. The method for forming a semiconductor structure according to claim 1, wherein the vapor phase epitaxy process comprises a step of forming the source/drain epitaxy layer doped with deuterium atoms with silicon-based gas and deuterium-based gas.

4. The method for forming a semiconductor structure according to claim 3, wherein the volume ratio of the deuterium-based gas is within 50% to 90%.

5. The method for forming a semiconductor structure according to claim 4, wherein the deuterium-based gas is deuterium gas or a mixture of deuterium gas and hydrogen gas, in which volume ratio of the deuterium gas with respect to the total volume of the mixture is within 2% to 98%.

6. The method for forming a semiconductor structure according to claim 3, wherein the silicon-based gas comprises at least one compound or combination of compounds chosen from a group of SiH₄, Si₂H₆, SiH₂Cl₂, SiHCl₃, SiCl₄, Si(CH₃)₄.

7. The method for forming a semiconductor structure according to claim 3, wherein a temperature to perform the vapor phase epitaxy process is within 800° C. to 1100° C., and the duration of the vapor phase epitaxy process is within 10 mins to 2000 mins.

8. The method for forming a semiconductor structure according to claim 1, wherein a thickness of the source/drain epitaxy layer is within 10 nm to 5000 nm.

9. A semiconductor structure, manufactured by the method of claim 1, comprising:
a semiconductor substrate, formed with a source/gate epitaxy layer doped with deuterium atoms; and
a gate structure, formed between the source/gate epitaxy layer doped with deuterium atoms above the semiconductor substrate, comprising a gate oxide layer doped with deuterium atoms.
